(19) United States
(12) Patent Application Publication
(10) Pub. No.: US 2013/0222986 A1
(43) Pub. Date: Aug. 29, 2013

(54) ELECTRONIC DEVICE INCLUDING LID-OPENING/CLOSING MECHANISM

(71) Applicant: SANYO Electric Co., Ltd., (US)

(72) Inventor: Yasuhiro Nakatsu, Osaka-shi (JP)

(73) Assignee: SANYO ELECTRIC CO., LTD., Osaka (JP)

(21) Appl. No.: 13/776,889

(22) Filed: Feb. 26, 2013

(30) Foreign Application Priority Data
Feb. 27, 2012 (JP) 2012-039510

(51) Int. Cl. H04N 5/225; H05K 5/02

(52) U.S. Cl. CPC H04N 5/2251; H05K 5/0239
USPC 361/679.01

(57) ABSTRACT

In an electronic device of the invention, a holding member which holds one end of an open/close lid is disposed in a device body. The open/close lid includes a lid portion covering an opening of the body, an arm projecting from one end of the lid portion, and an enlarged portion projecting from a tip end of the arm. A notch opens at the holding member, and the arm of the open/close lid penetrates the notch. A projection is formed on the holding member. The enlarged portion of the open/close lid slides on the projection in a process in which the open/close lid is opened. A surface of the projection is formed into a curved surface in which a cross section thereof extending along a turning surface of the open/close lid swells outward to define a turning locus in the process in which the open/close lid is opened.

### CROSS-REFERENCE TO RELATED APPLICATIONS

This application claims priority to Japanese Patent Application No. 2012-039510. The entirety of Japanese Patent Application No. 2012-039510 is incorporated by reference herein.

### BACKGROUND OF THE INVENTION

1. Field of the Invention

The present invention relates to an electronic device such as a digital camera and a cell-phone including a lid-opening/closing mechanism.

2. Description of Related Art

In a conventional electronic device such as a digital camera and a cell-phone, an open/close lid is mounted on a device body to cover an opening of a jack such as a USB connector such that the open/close lid can be opened and closed.

As a lid-opening/closing mechanism which connects the open/close lid to the device body such that the open/close lid can be opened and closed, there are systems in which an opening portion of the device body is exposed by pulling out the open/close lid from the device body in a separating direction of the open/close lid from the device body, and in which the opening portion of a device body is exposed by turning the open/close lid substantially around one end of the open/close lid as rotation center.

In the latter system, an arm bending in an arc form projects from one end of the open/close lid, the arm is made to loosely penetrate a through hole of the device body in the vicinity of its opening portion. According to this configuration, the open/close lid is supported such that it can be turned substantially around the one end as rotation center, and the opening portion is opened and closed by turning the open/close lid.

In the lid-opening/closing mechanism of the system in which the open/close lid is turned substantially around the one end of the open/close lid as rotation center, however, to turn the open/close lid smoothly, the through hole of the device body largely opens so that the arm projecting from the open/close lid penetrates the through hole with a sufficient margin. Therefore, there is a problem that turning motion of the open/close lid is not stabilized when a user operates to open the open/close lid, and operability of the open/close lid is poor.

### SUMMARY OF THE INVENTION

Hence, it is an object of the present invention to provide an electronic device including a lid-opening/closing mechanism capable of stabilizing the turning motion of the open/close lid when the open/close lid is opened.

An electronic device of the present invention includes a body having an opening portion, and an open/close lid which open and closes the opening portion of the body. One end of the open/close lid is connected to the body. The other end of the open/close lid is a free end. The open/close lid opens and closes the opening portion of the body by turning the other end of the open/close lid.

In the lid-opening/closing mechanism of the electronic device of the present invention, a holding member which holds the one end of the open/close lid is disposed in the body.

The open/close lid includes a plate-shaped lid portion covering the opening portion of the body, an arm portion projecting from one end of the lid portion and extending toward the body, and an enlarged portion which projects from a tip end of the arm portion and which is enlarged greater than the arm portion in its cross section extending along a turning surface of the open/close lid.

A notch opens at the holding member, and the arm portion of the open/close lid penetrates the notch with play. The enlarged portion of the open/close lid located in the body prevents the open/close lid from being pulled out.

A projection is formed on the holding member, and the enlarged portion of the open/close lid slides on the projection in the process in which the open/close lid is opened. A surface of the projection is formed into a curved surface in which a cross section thereof extending along the turning surface of the open/close lid swells outward to define a turning locus in the process in which the open/close lid is opened.

### BRIEF DESCRIPTION OF THE DRAWINGS

FIG. 1 is a perspective view of a digital camera according to an embodiment of the present invention as viewed from a front surface side thereof;

FIG. 2 is a perspective view of the digital camera as viewed from a rear surface side thereof;

FIG. 3 is a perspective view of a state where an open/close lid of the digital camera is opened as viewed from the front surface side thereof;

FIG. 4 is a perspective view of a state where the open/close lid of the digital camera is opened as viewed from the rear surface side thereof;

FIG. 5 is a perspective view showing the open/close lid and a holding member disposed on a chassis;

FIG. 6 is a perspective view showing the open/close lid and the holding member in a state where the open/close lid is opened;

FIG. 7 is an enlarged perspective view showing the open/close lid and the holding member in a closed state;

FIG. 8 is an enlarged perspective view showing the open/close lid and the holding member in an opened state;

FIG. 9 is a perspective view showing an assembled state of the open/close lid and the holding member;

FIG. 10 is a perspective view showing a disassembled state of the open/close lid and the holding member;

FIG. 11 is a sectional view showing a first stage of a process in which the open/close lid is opened from its fully closed state to its fully opened state;

FIG. 12 is an enlarged sectional view of an essential portion A shown in FIG. 11;

FIG. 13 is a sectional view showing a second stage of a process in which the open/close lid is opened from its fully closed state to its fully opened state;

FIG. 14 is an enlarged sectional view of a portion A shown in FIG. 13;

FIG. 15 is a sectional view showing a third stage of a process in which the open/close lid is opened from its fully closed state to its fully opened state;

FIG. 16 is an enlarged sectional view of a portion A shown in FIG. 15;

FIG. 17 is a sectional view showing a fourth stage of a process in which the open/close lid is opened from its fully closed state to its fully opened state;

FIG. 18 is an enlarged sectional view of a portion A shown in FIG. 17;

FIG. 19 is a sectional view showing a fifth stage of a process in which the open/close lid is opened from its fully closed state to its fully opened state; and

FIG. 20 is an enlarged sectional view of a portion A shown in FIG. 19.

### DETAILED DESCRIPTION OF THE PREFERRED EMBODIMENT

An embodiment in which the present invention is applied to a digital camera will be described in detail with reference to the drawings.

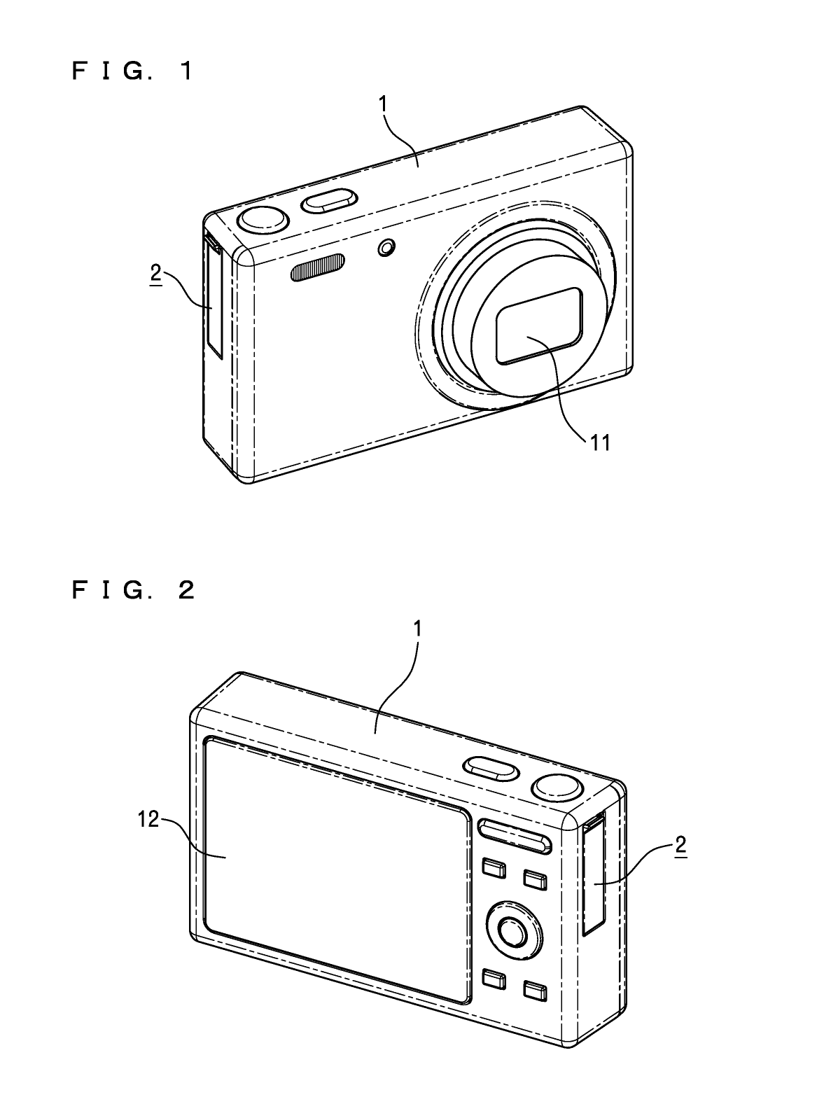

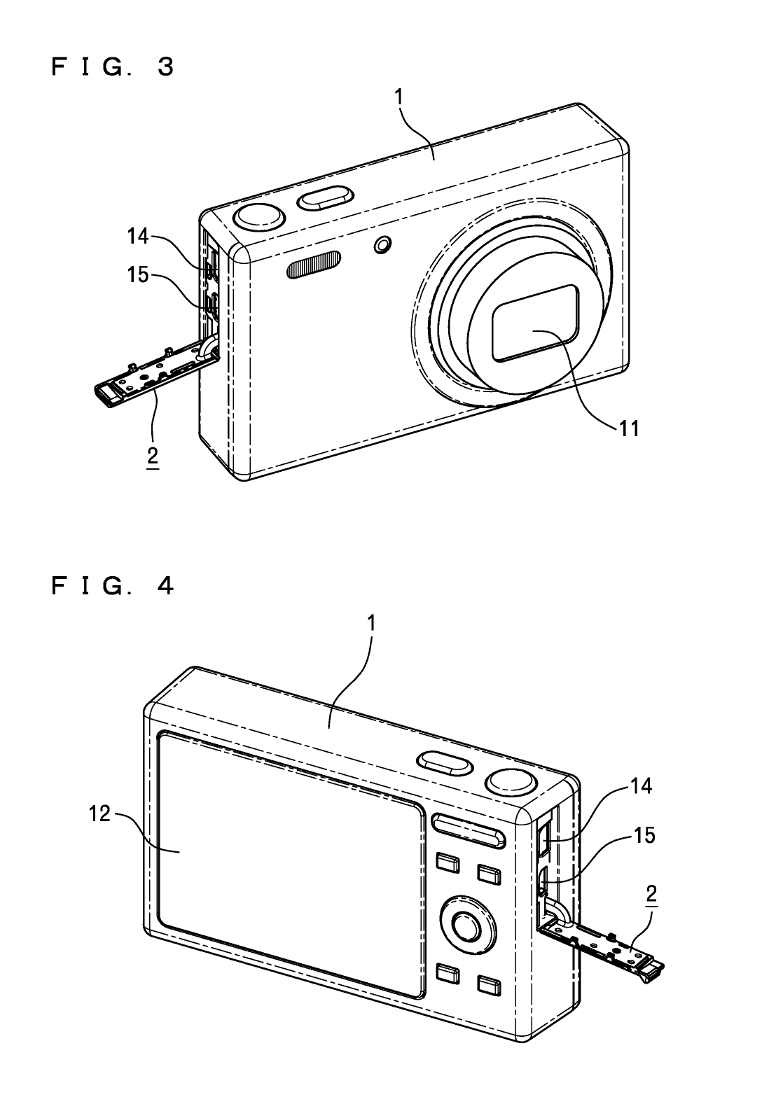

As shown in FIGS. 1 to 4, the digital camera according to the embodiment of the present invention includes a shooting window 11 provided on a front surface side of a body 1, a display 12 provided on a rear surface side of the body 1. An open/close lid 2 for closing opening portions 14 and 15 of a jack of a USB connector is disposed on a side surface of the body 1 such that the open/close lid 2 can be opened and closed.

The open/close lid 2 has a band plate shape which is vertically long in its closed state. By turning the open/close lid 2 substantially around its lower end as rotation center, the opening portions 14 and 15 are opened and closed.

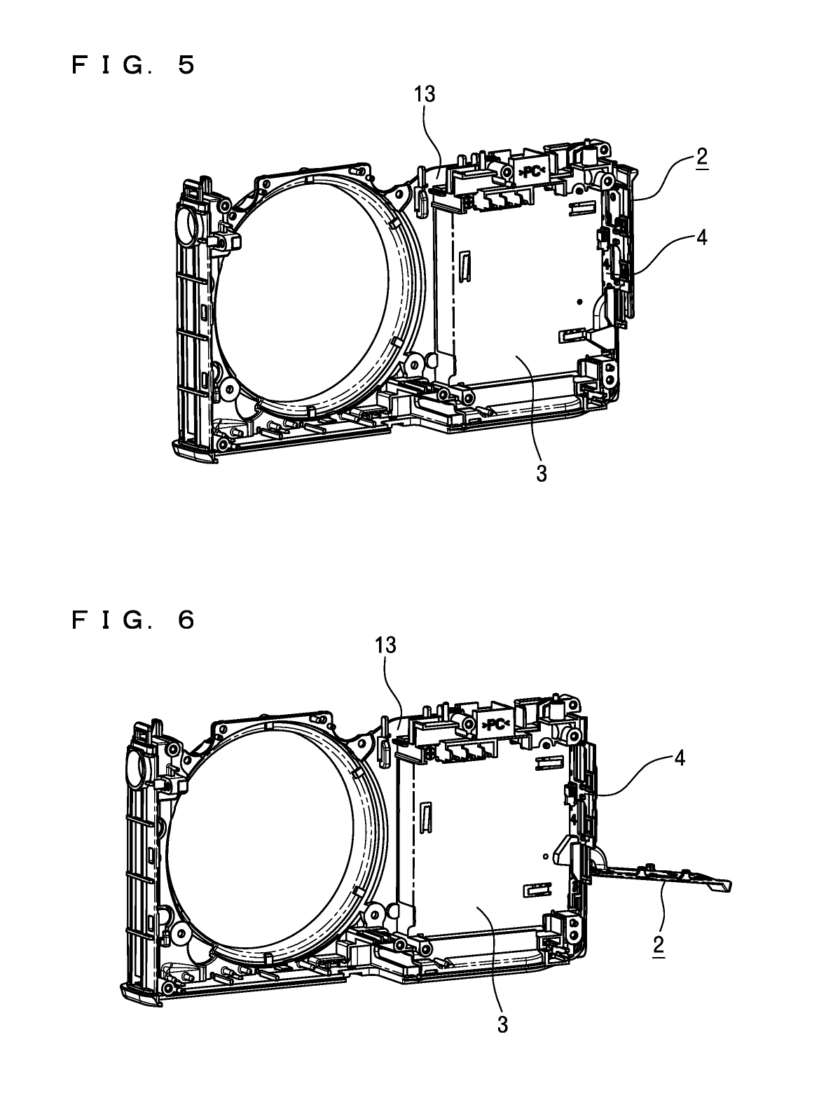

A chassis 13 made of synthetic resin as shown in FIGS. 5 and 6 is disposed in the body 1. A sheet metal member 3 for forming a battery chamber is mounted on an inner surface of the chassis 13.

A holding member 4 made of synthetic resin is fixed to a side of the chassis 13. A lower end of the open/close lid 2 is connected to the holding member 4.

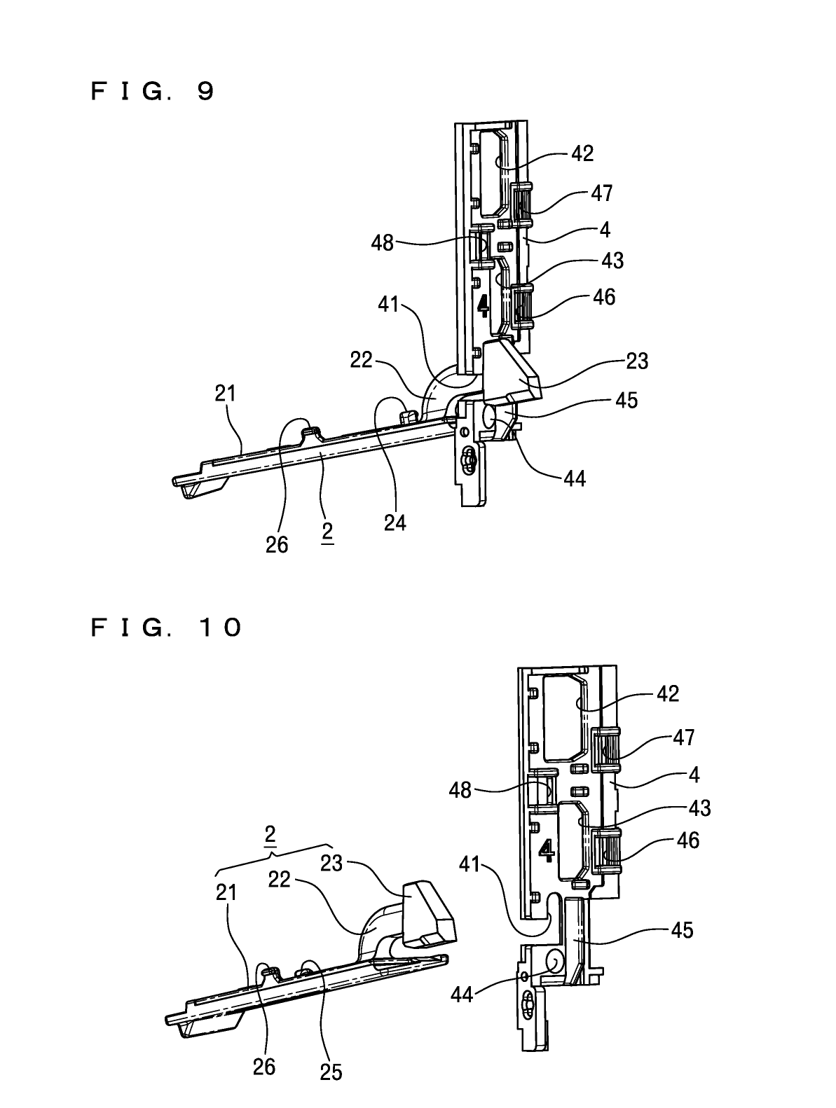

As shown in FIGS. 9 and 10, two opening 42 and 43 configuring the opening portions 14 and 15 are formed in the holding member 4. A notch 41 opens at lower positions of the opening 42 and 43, and a lower end of the open/close lid 2 penetrates the notch 41.

The open/close lid 2 includes a band-plate shaped lid portion 21 which closes the two opening 42 and 43, an arm portion 22 which projects from a lower end of the lid portion 21 and which extends in an L-form along a turning surface of the open/close lid 2, and an enlarged portion 23 which projects from a tip end of the arm portion 22 and which is enlarged greater than the arm portion 22 in a cross section of the open/close lid 2 along its turning surface.

A thickness of the enlarged portion 23 of the open/close lid 2 in the direction perpendicular to the turning surface of the open/close lid 2 is uniform.

The notch 41 of the holding member 4 has such a sufficient size that the arm portion 22 of the open/close lid 2 penetrates the notch 41, but that the enlarged portion 23 of the open/close lid 2 is prevented from passing through the notch 41.

Three hook pieces 24, 25, and 26 project from an inner surface of the lid portion 21 of the open/close lid 2, and engaged holes 46, 47, and 48 with which the three hook pieces 24, 25, and 26 should detachably be engaged open at the holding member 4.

A semi-spherical projection 44 is formed on an inner surface of the holding member 4 to which the enlarged portion 23 of the open/close lid 2 is opposed at a lower position of the notch 41, and a guide wall 45 projects from a side of the projection 44.

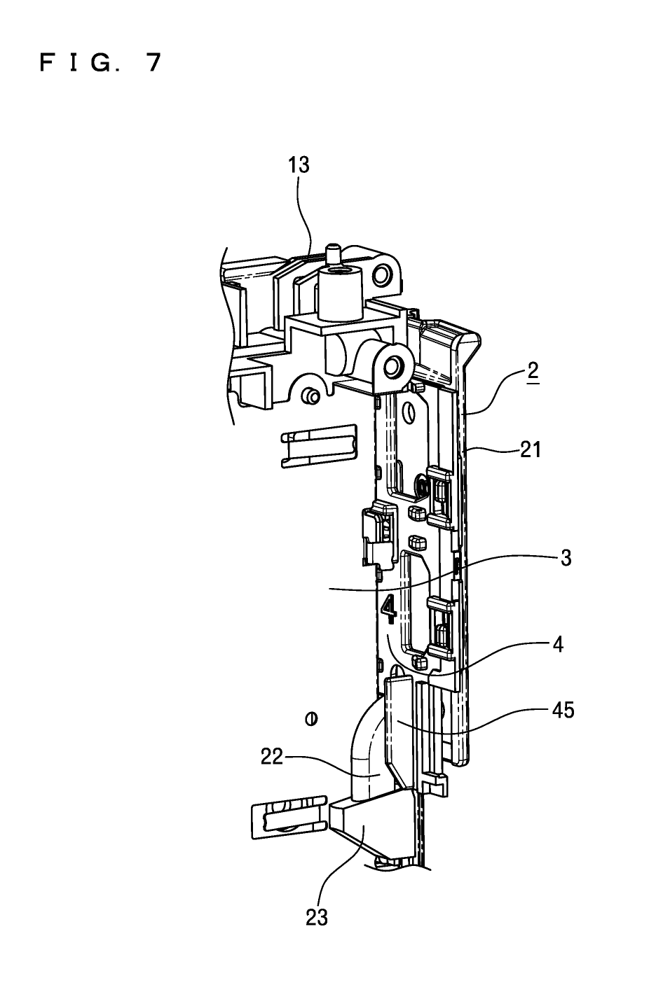

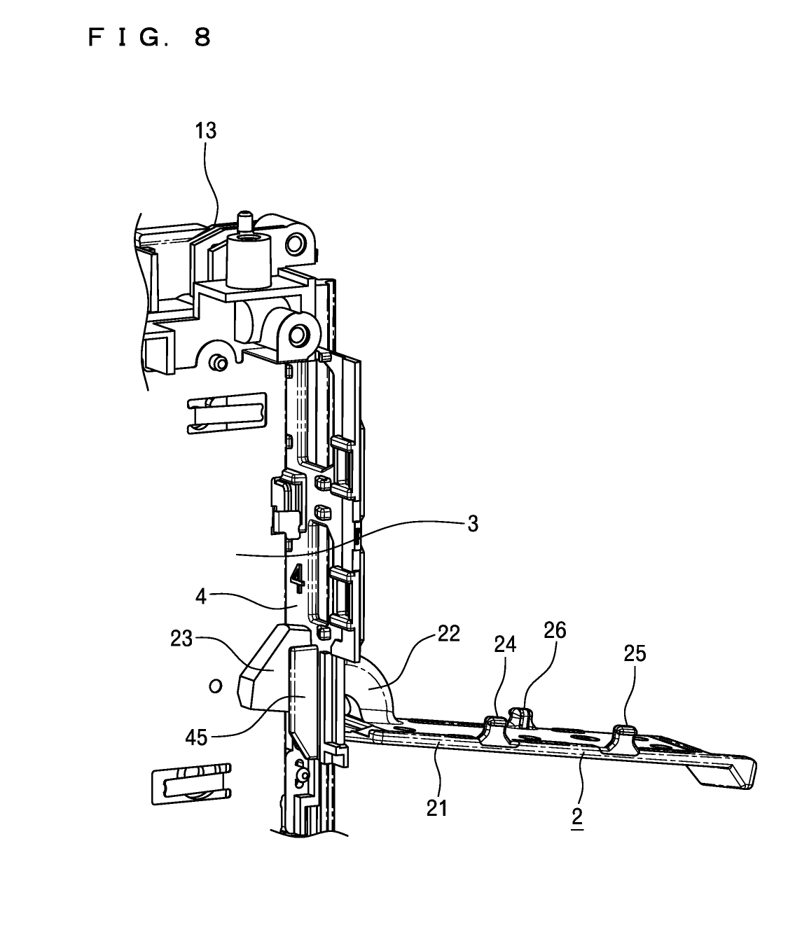

As shown in FIGS. 5 and 6, the open/close lid 2 is connected to the holding member 4. In a state where the sheet metal member 3 and the holding member 4 are mounted on the chassis 13, as shown in FIGS. 7 and 8, the enlarged portion 23 of the open/close lid 2 projects into the body, and the sheet metal member 3 and the guide wall 45 of the holding member 4 are disposed on both sides of the enlarged portion 23.

Therefore, in a process in which the open/close lid 2 is opened and closed between a fully closed state shown in FIG. 7 and a fully opened state shown in FIG. 8, the enlarged portion 23 of the open/close lid 2 is guided by a surface of the sheet metal member 3 and a side surface of the guide wall 45, and a turning surface of the open/close lid 2 is prevented from largely deviating.

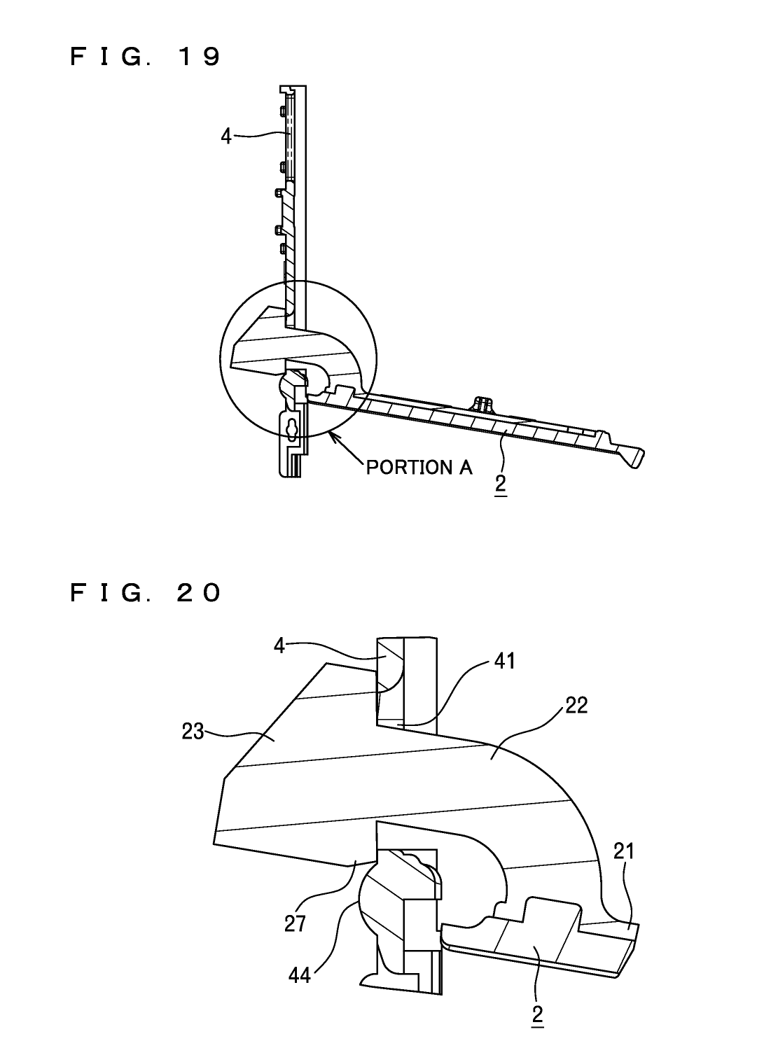

In this digital camera, in the process in which the open/close lid 2 is opened from the fully closed state shown in FIG. 7 to the fully opened state shown in FIG. 8, the open/close lid 2 turns while moving in a locus as shown in FIGS. 11 to 20.

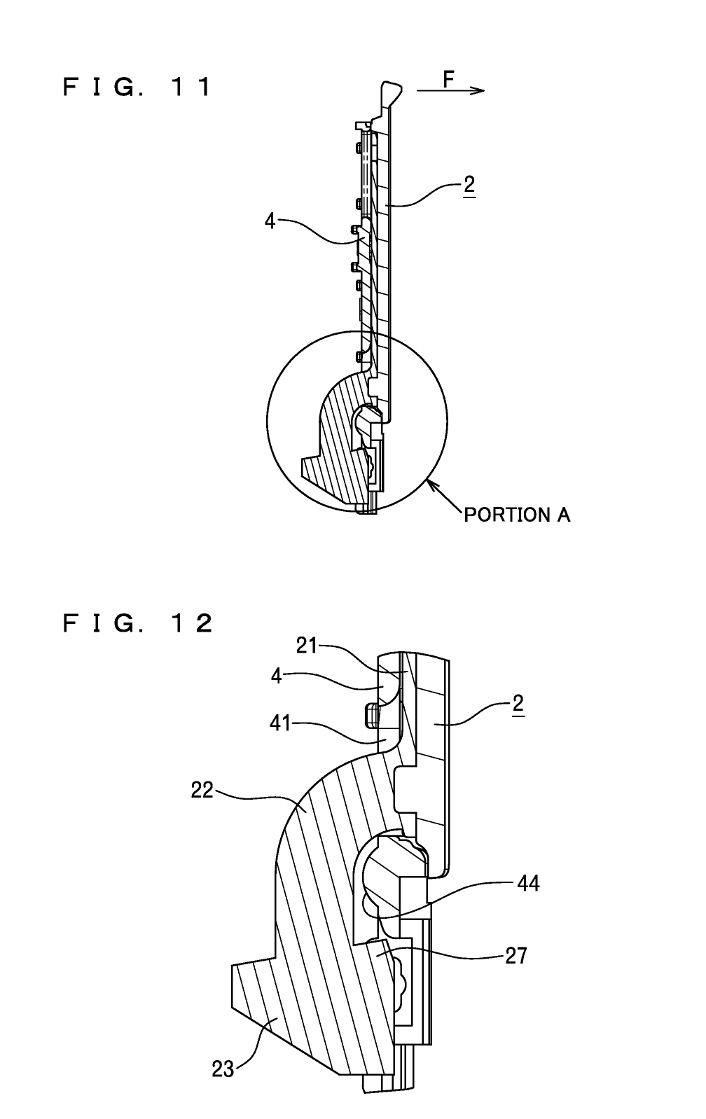

FIG. 11 shows the fully closed state of the open/close lid 2. In this state, as shown in FIG. 12, a base end of the arm portion 22 of the open/close lid 2 penetrates the notch 41 of the open/close lid 2, and an angle portion 27 of the enlarged portion 23 is separated from the projection 44 of the holding member 4.

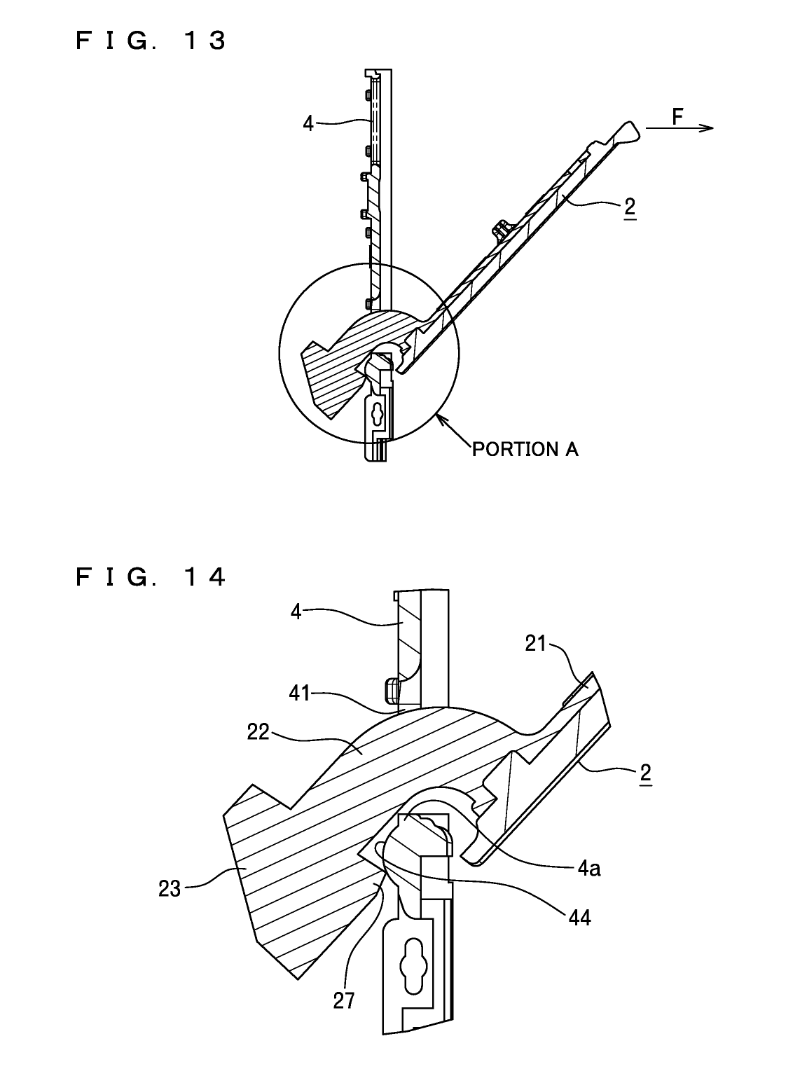

To open the open/close lid 2 from this state, when a finger is put on an upper end of the open/close lid 2 and an operation force F in an opening direction shown in FIG. 11 is applied, engagement between the hook pieces 24, 25, and 26 and the engaged holes 46, 47, and 48 is released, and the open/close lid 2 starts opening as shown in FIG. 13.

Here, the open/close lid 2 receives the operation force F in the opening direction, the open/close lid 2 moves in a direction separating from the holding member 4 and at the same time, the open/close lid 2 turns in the opening direction.

According to this operation, the arm portion 22 of the open/close lid 2 moves in the notch 41 of the holding member 4 in an escaping direction as shown in FIG. 14, the angle portion 27 of the enlarged portion 23 of the open/close lid 2 is brought into contact with the surface of the projection 44 of the holding member 4 under pressure.

Here, the angle portion 27 of the enlarged portion 23 of the open/close lid 2 abuts against the projection 44 of the holding member 4. According to this abutment, a case where the arm portion 22 of the open/close lid 2 slides on an opening edge 4a of the holding member 4 and large friction is generated is avoided. Therefore, it is possible to avoid a case where the opening action of the open/close lid 2 is hindered by this friction and the open/close lid 2 and the holding member 4 are deteriorated.

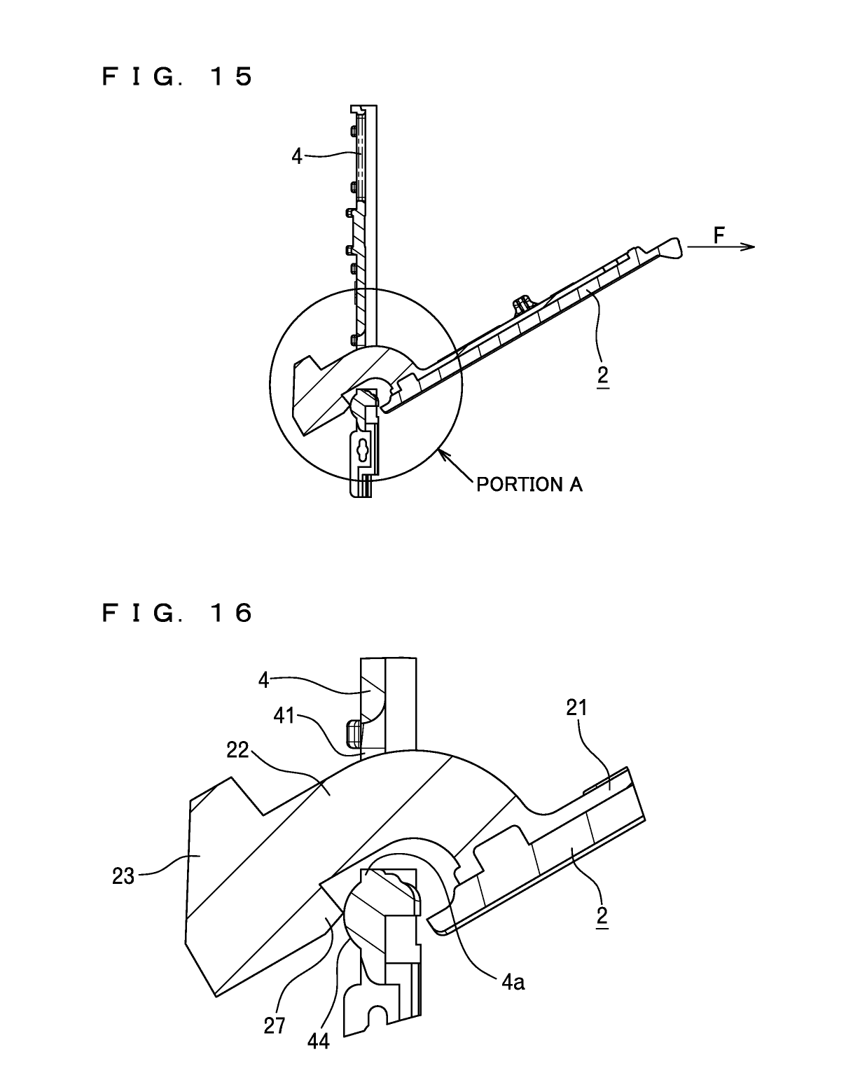

When the operation force F in the opening direction is applied to the open/close lid 2 as shown in FIG. 15, the arm portion 22 of the open/close lid 2 further moves in the notch 41 of the holding member 4 in the escaping direction as shown in FIG. 16, the angle portion 27 of the enlarged portion 23 of the open/close lid 2 slides on the projection 44 of the holding member 4, and a turning locus of the open/close lid 2 is defined.

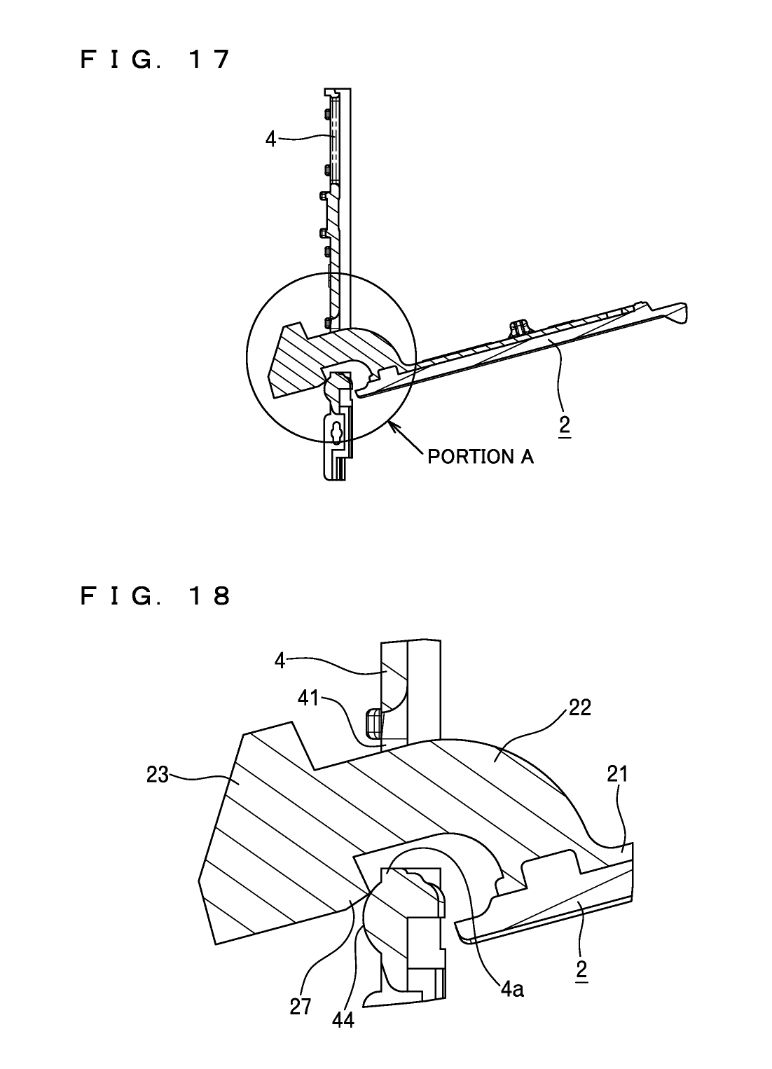

Thereafter, as shown in FIG. 17, the operation force is not applied to the open/close lid 2 almost at all, and the open/close lid 2 is opened to the fully opened state shown in FIG. 19 by gravity of its own.

In this process, as shown in FIGS. 18 and 19, the arm portion 22 of the open/close lid 2 further moves in the notch 41 of the holding member 4 in the escaping direction, the angle portion 27 of the enlarged portion 23 of the open/close lid 2 slides on the projection 44 of the holding member 4 and the turning locus of the open/close lid 2 is defined.

As described above, in the process in which a user opens the open/close lid 2, the enlarged portion 23 of the open/close lid 2 receives the force (operation force or gravity) applied to the open/close lid 2, the enlarged portion 23 is brought into contact with the projection 44 of the holding member 4 under pressure, and the enlarged portion 23 slides along the surface of the projection 44. According to this configuration, the turning locus of the open/close lid 2 from the fully closed state to the fully opened state is defined.

As a result, turning motion of the open/close lid 2 is stabilized when a user operates to open the open/close lid 2, and the operability is improved.

When the user operates to close the open/close lid 2, as shown in FIGS. 18, 16 and 14, the angle portion 27 of the enlarged portion 23 of the open/close lid 2 abuts against the projection 44 of the holding member 4. According to this abutment, the open/close lid 2 is pulled into the body 1. Therefore, it is possible to avoid a case where the arm portion 22 of the open/close lid 2 slides on the opening edge 4a of the holding member 4. As a result, the open/close lid 2 is closed smoothly, and the open/close lid 2 and the holding member 4 are not deteriorated.

Incidentally, the configuration of each of the constituent parts according to the present invention is not limited to those described preferred embodiment. Various changes can be made by those skilled in the art within the range not departing from the spirit of the present invention . For example, the projection 44 of the holding member 4 is not limited to the semi-spherical projection, and it is possible to employ various shapes only if a cross section of the projection 44 extending along the turning surface of the open/close lid 2 is a curved surface swelling outward such as a semi-columnar shape.

The holding member 4 is not limited to the independent molded article, and the holding member 4 can be formed integrally with the chassis 13 or a body cabinet.

Further, the present invention is not limited to the configuration in which a longitudinal end of the open/close lid 2 is connected to the body 1, and the present invention can be also applied to a configuration in which an end of the open/close lid 2 in a direction intersecting with the longitudinal direction at right angles is connected to the body 1.

What is claimed is:

1. An electronic device including a lid-opening/closing mechanism, comprising:
a body having an opening portion;
an open/ close lid which opens and closes the opening portion of the body, which has one end connected to the body and the other end is a free end, and which opens and closes the opening of the body by turning of the other end; and
a holding member, which is disposed in the body, which holds the one end of the open/close lid,
wherein, the open/close lid comprising:
a plate-shaped lid portion which covers the opening portion of the body;
an arm portion which projects from one end of the lid portion into the body; and
an enlarged portion which projects from a tip end of the arm portion and which is enlarged greater than the arm portion in its cross section extending along a turning surface of the open/close lid;
wherein, the holding member comprising:
a notch through which the arm portion of the open/close lid passes with play; and
a projection on which the enlarged portion of the open/close lid slides in a process in which the open/close lid is opened,
wherein, a surface of the projection is formed into a curved surface in which a cross section thereof extending along the turning surface of the open/close lid swells outward to define a turning locus in the process in which the open/close lid is opened.

2. The electronic device according to claim 1, wherein
the arm portion of the open/close lid is bent into an L-shape along the turning surface of the open/close lid.

3. The electronic device according to claim 1, wherein
a thickness of the enlarged portion of the open/close lid in a direction perpendicular to the turning surface of the open/close lid is uniform, and a pair of guide surfaces are formed on both sides which interpose the enlarged portion of the open/close lid, and the guide surfaces guide reciprocating motion of the enlarged portion with the turning of the open/close lid.

4. The electronic device according to claim 3, wherein
at least one of the pair of guide surfaces is formed on the holding member.

5. The electronic device according to claim 1, wherein
the enlarged portion of the open/close lid is brought into contact with a surface of the projection of the holding member under pressure by a force applied to the open/close lid in the process in which the open/close lid is opened.
